(19) United States
(12) Patent Application Publication
(10) Pub. No.: US 2024/0391762 A1
(43) Pub. Date: Nov. 28, 2024

(54) Packaging of microelectromechanical system devices

(71) Applicant: Teknologian tutkimuskeskus VTT Oy, Espoo (FI)

(72) Inventor: Jae-Wung Lee, Espoo (FI)

(21) Appl. No.: 18/699,329

(22) PCT Filed: Oct. 3, 2022
(86) PCT No.: PCT/FI2022/050658

§ 371 Date: Apr. 8, 2024

(30) Foreign Application Priority Data
Oct. 6, 2021 (FI) 20216035

(51) Int. Cl. B81C 1/00; B81B 7/00

(52) U.S. Cl. CPC B81C 1/00468; B81B 7/0032; B81B 2203/0315; B81B 2203/04; B81C 2201/0105; B81C 2201/013; B81C 2203/0136; B81C 2203/0145

(57) ABSTRACT

According to an example aspect of the present invention, there is provided a package for a Microelectromechanical System, MEMS, device comprising a cap layer and the MEMS device below the cap layer, at least two electrodes on a surface of the MEMS device to enable electrical functioning of the MEMS device, wherein each electrode is located on a horizontal plane and comprises metal to enable formation of an air-path, the air-path between the cap layer and the MEMS device to enable releasing of the MEMS device, at least a part of the air-path being on the same horizontal plane wherein the at least two electrodes are located and a side access port connected to the air-path to enable releasing of the MEMS device, wherein the side access port goes through the cap layer.

### FIELD

Embodiments of the present invention relate in general to electronics and more specifically to packaging, such as thin film packaging, of Microelectromechanical System, MEMS, devices.

### BACKGROUND

Microelectromechanical System, MEMS, devices are miniaturized mechanical and electro-mechanical elements, such as devices and structures that are made using the techniques of microfabrication. MEMS devices may be comprised of components between 1 and 100 micrometers in size and size of MEMS devices may range from 20 micrometers to a millimeter. Due to their small size, composition and extremely demanding manufacturing methods, MEMS devices are susceptible to electrical failures and mechanical damages. Therefore, MEMS devices need to be packaged, for example by sealing the device between two wafers.

In case of electronic packaging, a thin film may refer to a coating having a thickness from 1 μm to. 10 μm. At least in case of thin film packaging of Microelectromechanical System, MEMS, devices, mass loading and release times of the MEMS device need to be considered. If only an access port on top of the package is used, short release time may be provided but a malfunctioning of the device may be caused due to mass loading on a MEMS device. On the other hand, if only a side access port is used, mass loading may be avoided but damage may be caused to the MEMS device due to a long release time of etching chemical. There is therefore a need to provide solutions for thin film packaging that enable short release times without mass loading.

### SUMMARY OF THE INVENTION

According to some aspects, there is provided the subject-matter of the independent claims. Some embodiments are defined in the dependent claims.

According to a first aspect of the present invention, there is provided a package for a Microelectromechanical System, MEMS, device comprising a cap layer and the MEMS device below the cap layer, at least two electrodes on a surface of the MEMS device to enable electrical functioning of the MEMS device, wherein each electrode is located on a horizontal plane and comprises metal to enable formation of an air-path, the air-path between the cap layer and the MEMS device to enable releasing of the MEMS device, at least a part of the air-path being on the same horizontal plane wherein the at least two electrodes are located and a side access port connected to the air-path to enable releasing of the MEMS device, wherein the side access port goes through the cap layer.

Embodiments of the first aspect may comprise at least one feature from the following bulleted list or any combination:
said metal of each electrode comprises a part of at least one MEMS electrode line;
said metal comprises a part of at least one dummy electrode line;
the air-path is formed by etching at least one other part of the at least one dummy electrode line, preferably using xenon difluoride, XeF2;
the package further comprises an air gap between the at least two electrodes;
the MEMS device comprises an etching mark at a location of the air gap;
the package further comprises a sealing layer arranged to cover at least the cap layer and the side access port;
the package further comprises a cavity on an upper surface of the MEMS device, wherein the cavity is in between the cap layer and the MEMS device and the side access port is outside the cavity;
the side access port is separated from the cavity;
the air-path goes through a side of the cavity and is connected to the side access port outside the cavity;
the side access port is vertical and the air-path is horizontal;
the package is a thin film package.

According to a second aspect of the present invention, there is provided a method for manufacturing a package for a Microelectromechanical System, MEMS, device comprising, depositing a MEMS device and at least two electrodes on a surface of the MEMS device, wherein each electrode is located at a horizontal plane and comprises metal to enable formation of an air-path, depositing a cap layer on top of the MEMS device, forming the air-path such that the air-path is between the cap layer and the MEMS device to enable releasing of the MEMS device, at least a part of the air-path being on the same horizontal plane wherein the at least two electrodes are located, forming a side access port and connecting the side access port to the air-path to enable release of the MEMS device, wherein the side access port goes through the cap layer and releasing the MEMS device.

Embodiments of the second aspect may comprise at least one feature from the following bulleted list or any combination:
forming the air-path by etching at least one other part of the at least one dummy electrode line, preferably using xenon difluoride, XeF2;
forming an air gap between the at least two electrodes.

### BRIEF DESCRIPTION OF THE DRAWINGS

FIG. 1 illustrates a thin film package for MEMS device in accordance with at least some embodiments of the present invention;

FIGS. 2A-2I illustrate a method for manufacturing a thin film package for a MEMS device in accordance with at least some embodiments of the present invention;

FIG. 3A illustrates a top view of real and dummy electrode lines before etching in accordance with at least some embodiments of the present invention;

FIG. 3B illustrates a top view of real and dummy electrode lines after etching in accordance with at least some embodiments of the present invention.

### EMBODIMENTS

Embodiments of the present invention relate to packaging for Microelectromechanical System, MEMS, devices. Even though thin film packaging is used as an example, embodiments of the present invention may be applied to any suitable packaging of MEMS devices. According to the embodiments of the present invention, formation of an air-path for releasing a MEMS device of a thin film package may comprise etching at least one dummy electrode line, to avoid causing damage to the MEMS device while forming the air-path. The air-paths are formed on a side of a cap layer of the thin film package in a horizontal direction, to provide short release time of the MEMS as well as to avoid damage to the MEMS device due to mass loading on top of the cap layer when a sealing layer is deposited. Etching/releasing may start via all air paths and gaps, as etching gas may reach the MEMS device 14 quickly.

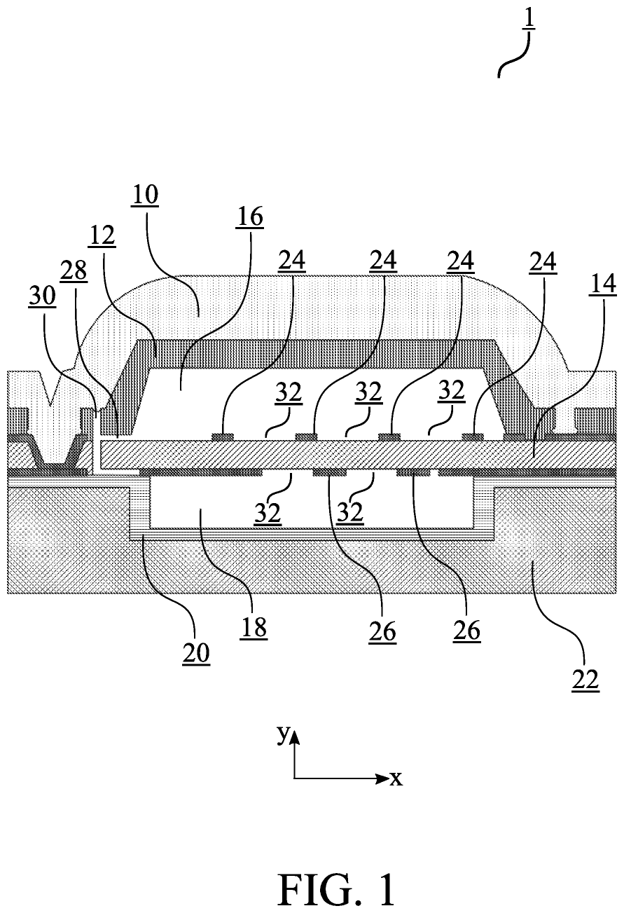

FIG. 1 illustrates an example of a thin film package in accordance with at least some embodiments of the present invention. More specifically, FIG. 1 illustrates an example of a thin film package 1, which may comprise a sealing layer 10. The sealing layer 10 may comprise insulating materials, such as silicon dioxide, SiO₂, aluminium nitride, AlN, aluminium oxide, Al₂O₃, silicon nitride, SiN, metals, such as aluminium, Al, molybdenum, Mo, titanium, Ti, metal and insulator combination, such as SiO₂+Al, AlN+Ti, or semiconductor materials, such as silicon, Si, germanium, Ge, etc.

The thin film package 1 may further comprise a cap layer 12 below the sealing layer 10. The cap layer may also comprise said insulating materials, said metals, said metal and insulator combinations or said semiconductor materials.

The thin film package 1 may further comprise a MEMS device 14 and a top cavity 16 between the MEMS device 14 and the cap layer 12. The MEMS device 14 may comprise AlN. The top cavity 16 may comprise sacrificial material before the MEMS device 14 is released. The top cavity 16 may be referred to as a Thin Film Packaging, TFP, cavity. The thin film package 1 may also comprise a bottom cavity 18 below the MEMS device 14. The bottom cavity 18 may comprise sacrificial material before the MEMS device 14 is released. The bottom cavity 18 may be referred to as a MEMS cavity. The bottom cavity 18 may be covered by a passivation layer 20. The passivation layer 20 may comprise for example SiN, silicon carbide, SiC or Al₂O₃. The thin film package 1 may also comprise a bottom substrate 22. The bottom substrate may comprise Si.

The thin film package 1 may also comprise top electrodes 24 deposited on an upper surface of the MEMS device 14. In some embodiments, the thin film package 1 may also comprise bottom electrodes 26 deposited on a bottom surface of the MEMS device 14. The thin film package 1 may further comprise an air-path 28 on an upper surface of the MEMS device 14 and a side access port 30 for releasing the MEMS device, i.e., for removing sacrificial material from the top cavity 16 and the bottom cavity 18. The air-path 28 may go through a side of the cap layer 16 on a horizontal plane wherein at least two top electrodes 24 are located, to enable releasing of the MEMS device 14. The side access port 30 is connected to the air-path 28 to enable release of the MEMS device 14 and removal of the sacrificial material from the top cavity 16 via the air-path 28 and the side access port 30 when the sealing layer 10 is absent, i.e., before depositing the sealing layer 10.

The thin film package 1 may further comprise at least one air gap 32 due to etching. Each air gap 32 may be in between two electrodes. For instance, there may be one air gap 32 between two subsequent top electrodes 24. Alternatively, or in addition, there may be one air gap 32 between two subsequent bottom electrodes 26.

So at least two electrodes, such as top electrodes 24, may be deposited on a surface of the MEMS device 14. Each electrode may comprise metal and be located at a horizontal plane to enable electrical functioning of the MEMS device 14 and formation of the air-path 28. The air-path 28 between the cap layer 12 and the MEMS device 14 may go through a side of the cap layer 12 in the horizontal direction to enable releasing of the sacrificial material to outside of the thin film package, thereby further enabling release of the MEMS device 14. Moreover, at least a part of the air-path 28 may be on the same horizontal plane wherein the at least two electrodes are located. The side access port 30 may go through the cap layer 12 as well, but in a vertical direction.

The expression “vertical” means a direction which is identical with the normal of the thin film package 1, such as the y-axis shown in FIG. 1, and the expression “horizontal” means a direction which is perpendicular to the normal of the thin film package 1, such as the x-axis shown in FIG. 1. That is, the air-path 28 may be horizontal and the side access port 30 may be vertical, to avoid mass loading on the MEMS device 14 and short release time of the MEMS device 14.

Each electrode 24, 26 may comprise a part of at least one real electrode line and a part of at least one dummy electrode line, to enable forming of the air-path 28 by etching at least one other part of the at least one dummy electrode line at the location of the air-path 28. For instance, the air-path 28 may be formed by etching the at least one other part of the at least one dummy electrode line

The side access port 30 may be referred to as another air-path as well, because the sacrificial material may be released from the top cavity 16 to outside of the thin film package 1 via the air-path 28 and the side access port 30. The side access port 30 may be outside of the top cavity 16 and separated from the top cavity 16. The air-path 28 may go through a side of the top-cavity in the horizontal direction and be connected to the side access port 30 outside the cavity.

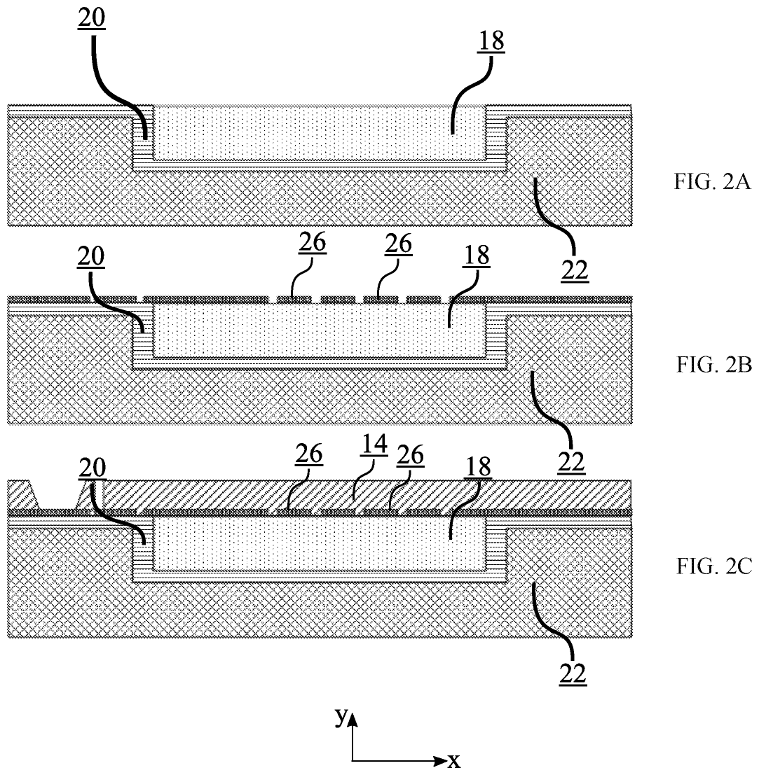

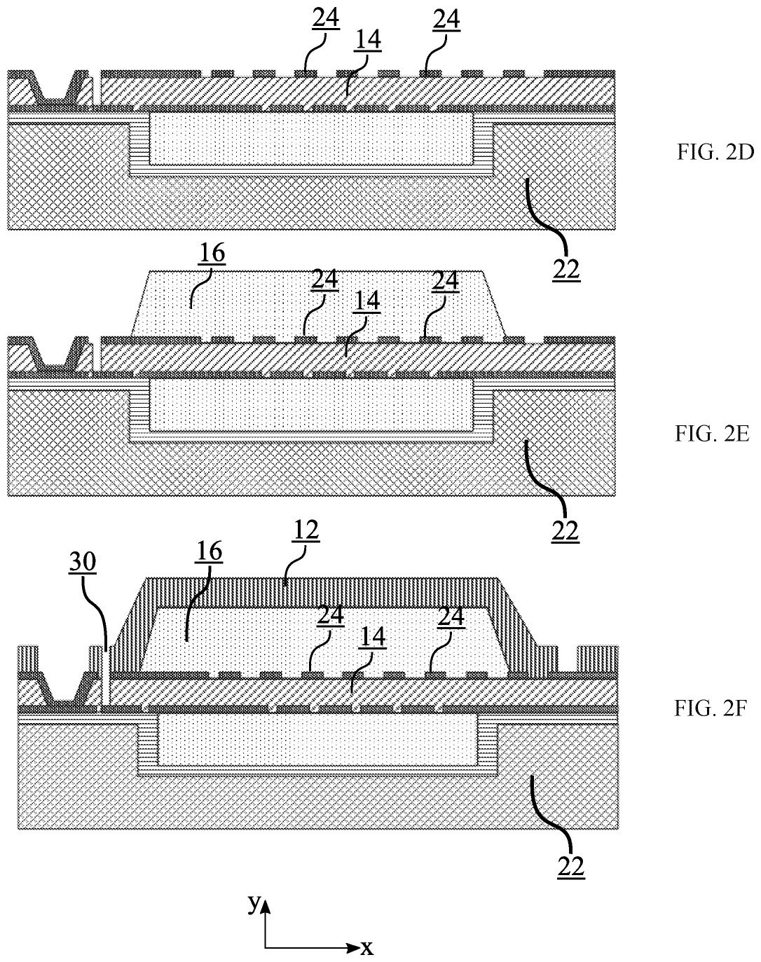

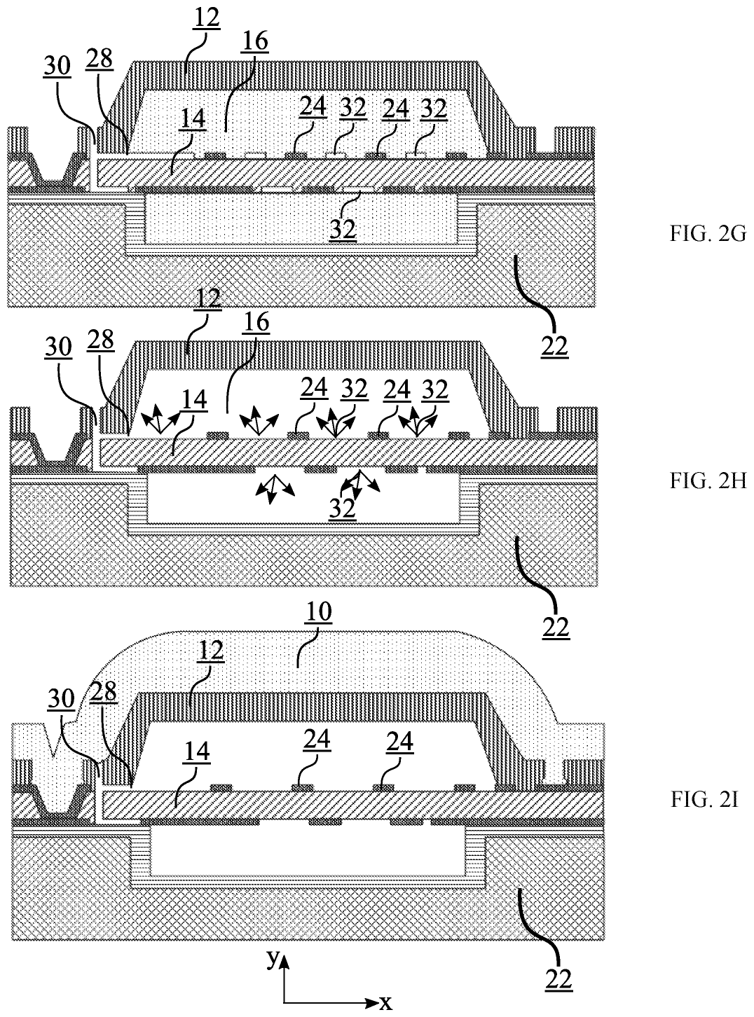

FIGS. 2A-2H illustrate a method for manufacturing a thin film package for a MEMS device in accordance with at least some embodiments of the present invention. At the step shown in FIG. 2a, the bottom cavity 18 may be formed. The bottom cavity 18 may be referred to as a 1^{st} sacrificial layer pocket. The bottom substrate 22, such as Si, may be etched to form a cavity and the passivation layer 20 may be deposited on the formed cavity, to generate the bottom cavity 18. The passivation layer 20 may comprise SiN, SiC or Al₂O₃. The bottom cavity 18 may be filled with sacrificial material, such as SiO₂.

At the step shown in FIG. 2B, a bottom electrode line may be deposited on top of the bottom cavity 18 and the bottom surface 22. The bottom electrode line may be patterned to form at least two bottom electrodes 26. That is, the at least two bottom electrodes 26 may be deposited on top of the bottom cavity 18 and the passivation layer 20. The bottom electrode line and the at least two bottom electrodes 26 may comprise Mo. Some parts of the bottom electrode line may comprise the at least two bottom electrodes 26 and the at least two bottom electrodes 26 may further comprise a combination of a real electrode line and dummy electrode line. Some other parts of the bottom electrode line may comprise only dummy electrode line, but not real electrode line. Said other parts of the bottom electrode line comprising only the dummy electrode line may be etched away later, to generate the air gaps 32 (shown in FIG. 1, but not shown in FIG. 2B).

At the step shown in FIG. 2C, the MEMS device 14 may be deposited on top of the patterned bottom electrode line, i.e., on top of the at least two bottom electrodes 26. The MEMS device 14 may be referred to as a MEMS device layer as well. The MEMS device 14 may comprise for example an AlN or ScAlN device layer. The MEMS device 14 may be patterned as well.

At the step shown in FIG. 2D, a top electrode line may be deposited on top of the MEMS device 14. The top electrode line may be patterned to form at least two top electrodes 24. That is, the at least two top electrodes 24 may be deposited on top of the MEMS device. The top electrode line and the at least two top electrodes 24 may comprise Mo. Some parts of the top electrode line may comprise the at least two top electrodes 24 and the at least two bottom electrodes 24 may further comprise a combination of the real electrode line and dummy electrode line. Some other parts of the top electrode line may comprise only dummy electrode line, but not real electrode line. Said other parts of the top electrode line may be etched away later, to generate the air gaps 32 (shown in FIG. 1 but not shown in FIG. 2B).

At the step shown in FIG. 2E, the top cavity 16 may be formed on top of the MEMS device 14 and the at least two top electrodes 24. The top cavity 16 may be referred to as a 2^{nd} sacrificial layer pocket. The top cavity 16 may be referred to as a 2^{nd} sacrificial layer pocket. The top cavity 16 may be formed by depositing and patterning sacrificial material, such as such as SiO₂.

At the step shown in FIG. 2F, the cap layer 12 may be deposited to cover at least the top cavity 16, and possibly at least parts of the MEMS device 14, wherein said parts of the MEMS 14 device may not be under the sacrificial material of the top cavity 16. Hence, the cap layer 12 may be deposited on top of the MEMS device 14, using the top cavity 16 as support. As shown in FIG. 2F, the cap layer 12 may be patterned as well. The cap layer 12 may comprise for example AlN or ScAlN. The side access port 30 may be formed by etching the cap layer 12 in a vertical direction, at least through the top electrode line and possibly through the MEMS device 14 and the bottom electrode line.

At the step shown in FIG. 2G, the air-path 28 may be formed. The air-path 28 may be formed by etching parts of the dummy electrode line, using XeF2 for example. Air gaps 32 may be formed by said etching as well. The air gaps 32 may be for upper sac layer etching. Etching of the dummy electrode line may generate etching marks at the locations of the air-path 28 and the air gaps 32.

At the step shown in FIG. 2H, the sacrificial material within the top cavity 16 and the bottom cavity 18 may be removed by etching. Said etching of the 1st and 2nd sacrificial layer may be performed for MEMS device releasing, Vapour Hydrogen fluoride, VHF, release. The MEMS device 14 may be then released by removing the sacrificial material through the air-path 28 and the side channel port 30. For instance, oxide may be released by VHF (360 nm/hr) and Si released by XeF2 (2760 nm/hr). That is, the oxide layer, when removed, may release the MEMS device 14 and allow free movement. The arrows shown in FIG. 2H demonstrate possible directions of etching gas to release the MEMS device 14.

At the step of FIG. 2I, the sealing layer 10 may be deposited. The sealing layer 10 may be deposited to cover at least the cap layer 12 and the side access port 30. The sealing layer 10 may comprise SiO₂ for example. Thus, the release holes, such as the air-path 28 and the side channel port 30, may be sealed without loading any mass on the MEMS device 14. Vacuum level of the thin film packaging may be the same with different sealing layer deposition pressures, e.g., 5 mtorr for the metal sputtering, 1000 mtorr for SiO2 Plasma Enhanced Chemical Vapour Deposition, PECVD, and larger than 5 mtorr for metal evaporation.

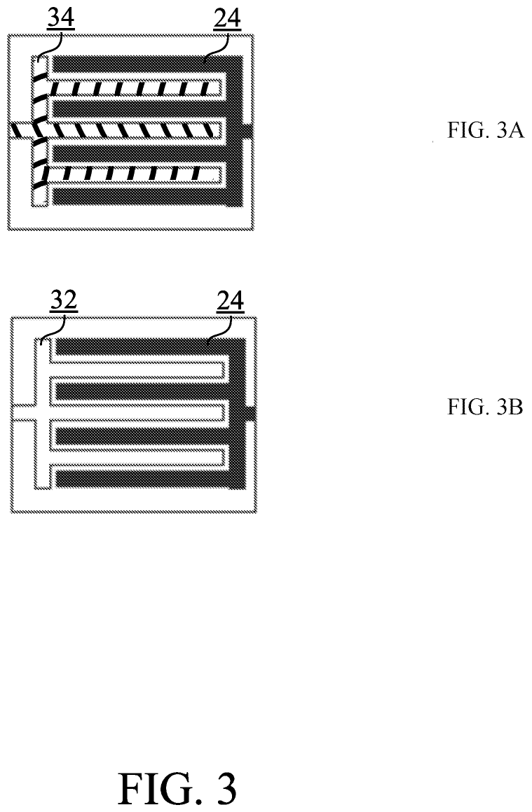

FIG. 3A illustrates a top view of real and dummy electrode lines before etching in accordance with at least some embodiments of the present invention. Dummy electrode line 34 may be separated from real electrode line, i.e., a line comprising real electrodes, such as top electrodes 24, after electrode patterning. Dummy electrodes may be connected together to for dummy electrode line 34. Real electrode line may refer to an electrical line for MEMS devices, i.e., an electrical line which works for MEMS devices. Dummy electrode line may refer to an electrical line which does not work for MEMS devices.

FIG. 3B illustrates a top view of real and dummy electrode lines after etching in accordance with at least some embodiments of the present invention. The dummy electrode line 34 shown in FIG. 3A may be etched away to form air gaps 32, shown for example in FIG. 2H in addition to FIG. 3B.

It is to be understood that the embodiments of the invention disclosed are not limited to the particular structures, process steps, or materials disclosed herein, but are extended to equivalents thereof as would be recognized by those ordinarily skilled in the relevant arts. It should also be understood that terminology employed herein is used for the purpose of describing particular embodiments only and is not intended to be limiting.

Reference throughout this specification to one embodiment or an embodiment means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment. Where reference is made to a numerical value using a term such as, for example, about or substantially, the exact numerical value is also disclosed.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and example of the present invention may be referred to herein along with alternatives for the various components thereof. It is understood that such embodiments, examples, and alternatives are not to be construed as de facto equivalents of one another, but are to be considered as separate and autonomous representations of the present invention.

Furthermore, the described features, structures, or characteristics may be combined in any suitable manner in one or more embodiments. In the preceding description, numerous specific details are provided, such as examples of lengths and widths as electrical dimensions (i.e., as a function of a used wavelength), shapes, etc., to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

While the forgoing examples are illustrative of the principles of the present invention in one or more particular applications, it will be apparent to those of ordinary skill in the art that numerous modifications in form, usage and details of implementation can be made without the exercise of inventive faculty, and without departing from the principles and concepts of the invention. Accordingly, it is not intended that the invention be limited, except as by the claims set forth below.

The verbs “to comprise” and “to include” are used in this document as open limitations that neither exclude nor require the existence of also un-recited features. The features recited in depending claims are mutually freely combinable unless otherwise explicitly stated. Furthermore, it is to be understood that the use of “a” or “an”, that is, a singular form, throughout this document does not exclude a plurality.

### INDUSTRIAL APPLICABILITY

At least some embodiments of the present invention find industrial application in thin film packaging for MEMS devices.

### ACRONYMS LIST

MEMS Microelectromechanical System
PECVD Plasma Enhanced Chemical Vapor Deposition
TFP Thin Film Package
VHF Vapour HF

REFERENCE SIGNS LIST

| | |
|---|---|
| 1 | Thin film package |
| 10 | Sealing layer |
| 12 | Cap layer |
| 14 | MEMS device |
| 16 | Top cavity |
| 18 | Bottom cavity |
| 20 | Passivation layer |
| 22 | Bottom substrate |
| 24 | Top electrodes |
| 26 | Bottom electrodes |
| 28 | Air-path |
| 30 | Side access port |
| 32 | Air gap |
| 34 | Dummy electrode line |

1. A package for a Microelectromechanical System, MEMS, device comprising:
a cap layer and the MEMS device below the cap layer;
at least two electrodes on a surface of the MEMS device to enable electrical functioning of the MEMS device, wherein each electrode is located on a horizontal plane and comprises metal to enable formation of an air-path;
the air-path between the cap layer and the MEMS device to enable releasing of the MEMS device, at least a part of the air-path being on the same horizontal plane wherein the at least two electrodes are located; and
a side access port connected to the air-path to enable releasing of the MEMS device, wherein the side access port goes through the cap layer.

2. The package according to claim 1, wherein said metal of each electrode comprises a part of at least one MEMS electrode line.

3. The package according to claim 1, wherein said metal comprises a part of at least one dummy electrode line.

4. The package according to claim 3, wherein the air-path is formed by etching at least one other part of the at least one dummy electrode line.

5. The package according to claim 1, further comprising:
an air gap between the at least two electrodes.

6. The package according to claim 1, further comprising:
a sealing layer arranged to cover at least the cap layer and the side access port.

7. The package according to claim 1, further comprising:
a cavity on an upper surface of the MEMS device, wherein the cavity is in between the cap layer and the MEMS device and the side access port is outside the cavity.

8. The package according to claim 7, wherein the side access port is separated from the cavity.

9. The package according to claim 7, wherein the air-path goes through a side of the cavity and is connected to the side access port outside the cavity.

10. The package according to claim 1, wherein the side access port is vertical and the air-path is horizontal.

11. The package according to claim 1, wherein the package is a thin film package.

12. A method for manufacturing a package for a Microelectromechanical System, MEMS, device comprising:
depositing a MEMS device and at least two electrodes on a surface of the MEMS device, wherein each electrode is located at a horizontal plane and comprises metal to enable formation of an air-path;
depositing a cap layer on top of the MEMS device;
forming the air-path such that the air-path is between the cap layer and the MEMS device to enable releasing of the MEMS device, at least a part of the air-path being on the same horizontal plane wherein the at least two electrodes are located;
forming a side access port and connecting the side access port to the air-path to enable release of the MEMS device, wherein the side access port goes through the cap layer; and
releasing the MEMS device.

13. The method according to claim 12, further comprising:
forming the air-path by etching at least one other part of at least one dummy electrode line.

14. The method according to claim 12, further comprising: forming an air gap between the at least two electrodes.

15. The package of claim 4, wherein xenon difluoride, XeF2, is used to form the air-path.

16. The method of claim 13, wherein xenon difluoride, XeF2, is used to form the air-path.
